(19) United States
(12) Patent Application Publication
(10) Pub. No.: US 2024/0337019 A1
(43) Pub. Date: Oct. 10, 2024

(54) AN ATOMIC LAYER DEPOSITION APPARATUS AND AN ARRANGEMENT

(71) Applicant: BENEQ OY, Espoo (FI)

(72) Inventors: Olli-Pekka SUHONEN, Espoo (FI); Matti MALILA, Espoo (FI); Pekka SOININEN, Espoo (FI); Markus BOSUND, Espoo (FI); Pasi MERILÄINEN, Espoo (FI)

(21) Appl. No.: 18/681,930

(22) PCT Filed: Aug. 12, 2022
(86) PCT No.: PCT/FI2022/050524

§ 371 Date: Feb. 7, 2024

(30) Foreign Application Priority Data
Aug. 13, 2021 (FI) 20215855

(51) Int. Cl. C23C 16/455; C23C 16/458; C23C 16/46

(52) U.S. Cl. CPC C23C 16/45546; C23C 16/4586; C23C 16/46

(57) ABSTRACT

An atomic layer deposition apparatus arranged to process multiple substrates concurrently in a batch process, the atomic layer deposition apparatus having a vacuum chamber, and a reaction chamber arranged inside the vacuum chamber. The reaction chamber includes a support part for supporting a substrate rack provided inside the reaction chamber, and a cover part for forming a housing surrounding the substrate rack provided at the support part. The atomic layer deposition apparatus further includes a conductive heater arranged to the reaction chamber; the conductive heater is arranged to provide thermal energy to substrates provided in the substrate rack inside the reaction chamber. The invention also relates to an arrangement having a substrate rack inside the reaction chamber.

### FIELD OF THE INVENTION

The present invention relates to an atomic layer deposition apparatus and more particularly to an atomic layer deposition apparatus according to the preamble of the independent claim 1.

The present invention further relates to an arrangement for processing multiple substrates, and more particularly to an arrangement according to the preamble of the independent claim 11.

### BACKGROUND OF THE INVENTION

In a traditional atomic layer deposition apparatus, the reaction chamber arranged inside the vacuum chamber is heated with radiation heaters using reflectors to avoid excess waste heat to the vacuum chamber, which is an outer chamber. Due to vacuum environment, the heat is not effectively transferred between the vacuum chamber and the reaction chamber in a nested chamber arrangement because in vacuum conditions there is no air circulation in the space between the chambers. Heat transfer through radiation is not very effective way to transfer heat unless the source temperature is much higher than the target body temperature. On the other hand, it is not wise to keep the heater temperature high in a technical way. The transfer of thermal energy from the heater to the reaction chamber via radiation is slow method and energy loss to the outer chamber is also higher.

### BRIEF DESCRIPTION OF THE INVENTION

An object of the present invention is to provide an effective way to provide heat to the reaction chamber such that the heat is transferred equally to substrates provided in a substrate rack inside the reaction chamber.

The objects of the invention are achieved by an atomic layer deposition apparatus and an arrangement which are characterized by what is stated in the independent claims. The preferred embodiments of the invention are disclosed in the dependent claims.

The invention is based on the idea of providing thermal energy for the substrates placed in the reaction chamber in their vicinity so that no waste heat is generated. This is achieved by an atomic layer deposition apparatus arranged to process multiple substrates concurrently in a batch process having a vacuum chamber, and a reaction chamber arranged inside the vacuum chamber. The reaction chamber comprises a support part for supporting a substrate rack provided inside the reaction chamber, and a cover part for forming a housing surrounding the substrate rack provided at the support part. The atomic layer deposition apparatus further comprises a conductive heater arranged to the reaction chamber; the conductive heater is arranged to provide thermal energy to substrates provided in the substrate rack inside the reaction chamber.

The conductive heater is arranged to provide heat through conduction in the structures of the reaction chamber. The substrate rack holds the substrate at the substrate rack such that none of the substrates are directly in contact with the reaction chamber. The substrate rack on the other hand is in contact with the reaction chamber.

The atomic layer deposition apparatus according to the invention comprising the conductive heater means that the atomic layer deposition apparatus comprises one or more conductive heaters arranged to the reaction chamber. The conductive heater is arranged to the reaction chamber means that the conductive heater is arranged on the reaction chamber, in the reaction chamber or within the reaction chamber. This means that the conductive heater may be arranged in connection with the outer surface of the reaction chamber, in connection with the inner surface of the reaction chamber, i.e., in a reaction space inside the reaction chamber, or within a structure forming the reaction chamber.

The reaction chamber comprises the cover part and the support part which are separately arranged, i.e., separate parts without continuous contact with each other. The support part having a rack support which is arranged to hold the substrate rack on the support part. The substrate rack comprises multiple substrate supports arranged one on top of the other or side by side.

According to the invention the conductive heater is arranged to the support part. When the conductive heater is arranged to the support part it provides thermal energy inside the reaction chamber to the reaction space surrounded by the cover part. The distribution of thermal energy then comes from one direction, producing heat evenly.

According to the invention the conductive heater is arranged to the cover part. Alternatively, or in addition to the previous embodiment, where the conductive heater is arranged in the support part, the conductive heater can thus be arranged in the cover part. The conductive heater being arranged to the cover part provides more effective way to heat the reaction space and the substrates in the substrate rack because the thermal energy comes from the structure surrounding the substrate rack.

The conductive heater may be for example an electric resistance heater.

The conductive heater is arranged direct contact with the support part or the cover part for efficient heat transfer.

In some embodiments of the invention the conductive heater is arranged inside a structure of the reaction chamber.

In some embodiments of the invention the conductive heater is embedded inside a structure of the reaction chamber. The embedded conductive heater is provided as integral part of the structure of the reaction chamber and in direct contact with the structure. The conductive heater may be moulded inside the structure.

According to the invention the conductive heater comprises a thermal element arranged inside a structure of the reaction chamber. The thermal element can be for example a hot plate provided inside the structure and conducting heat to the surface of the structure.

The thermal element may be a hot plate having a heater element, such as, electric resistance heater, embedded inside the hot plate.

According to the invention the conductive heater comprises a thermal element embedded inside a structure of the reaction chamber. The embedded thermal element is provided as integral part of the structure of the reaction chamber and in direct contact with the structure. The thermal element may be moulded inside the structure.

According to the invention the support part is arranged to form a base of the reaction chamber on which the substrate rack is provided, and the thermal element is arranged inside the base of the reaction chamber. In other words, the thermal element is embedded to the base of the reaction chamber, inside the base structure on which the substrate rack is placed. The thermal element thereby conducts heat to the surface of the base on the side of the reaction space, and thus heats the substrates arranged on the substrate rack standing on the base in the reaction space.

According to the invention the cover part forming the housing comprises reactor side walls and a reactor roof, and the thermal element is provided inside the reactor roof. Alternatively, the cover part forming the housing comprises reactor side walls and a reactor roof, and the thermal element is provided inside the reactor side walls. Alternatively, the cover part forming the housing comprises reactor side walls and a reactor roof, and the thermal element is provided inside the reactor side walls and the reactor roof.

In other words, the thermal element may be provided to the cover part inside the roof structure, or inside the side wall structure, or inside both the roof structure and the side wall structure. The thermal element may be embedded to the cover part such that it extends throughout the covert part providing heat distribution evenly to the reaction space surrounded by the cover part.

According to the invention the thermal element is provided inside the base of the reaction chamber and inside the reactor roof, or alternatively, the thermal element is provided inside the base of the reaction chamber and inside the reactor side walls, or alternatively, the thermal element is provided inside the base of the reaction chamber and inside the reactor roof and inside the reactor side walls. Alternatively, the thermal element is provided in connection with the base of the reaction chamber and in connection with the reactor roof, or alternatively, the thermal element is provided in connection with the base of the reaction chamber and in connection with the reactor side walls, or alternatively, the thermal element is provided in connection with the base of the reaction chamber and in connection with the reactor roof and inside the reactor side walls. Alternatively, the thermal element is provided inside the base of the reaction chamber and in connection with the reactor roof, or alternatively, the thermal element is provided inside the base of the reaction chamber and in connection with the reactor side walls, or alternatively, the thermal element is provided inside the base of the reaction chamber and in connection with the reactor roof and in connection with the reactor side walls. Alternatively, the thermal element is provided in connection with the base of the reaction chamber and inside the reactor roof, or alternatively, the thermal element is provided in connection with the base of the reaction chamber and inside the reactor side walls, or alternatively, the thermal element is provided in connection with the base of the reaction chamber and inside the reactor roof and inside the reactor side walls. The thermal element can also be arranged inside or in connection with the base of the reaction chamber so that the reactor side walls have a thermal element inside or in connection with said reactor side walls and/or the reactor roof has a thermal element inside or in connection with said reactor roof.

In some embodiments, the reaction chamber comprises a heater cavity having a cavity space. The cavity space is defined by inner surfaces of the cavity space.

The heater cavity is provided to a structure of the reaction chamber or in connection with the structure of the reaction chamber.

In some embodiments, the heater cavity is provided inside the structure of the reaction chamber.

In some other embodiments, the reaction chamber comprises the thermal element and the heater cavity is provided to the thermal element. The thermal element is further provided in connection with the structure of the reaction chamber or inside the structure of the reaction chamber.

The conductive heater is arranged inside the heater cavity. Accordingly, conductive heater is arranged to heat the cavity space and/or inside the cavity space.

In some embodiments, the conductive heater is arranged inside the heater cavity in a loose fit. The loose fit means that the conductive heater is arranged inside the heater cavity such that there is space or a gap between conductive heater and at least one of the inner surfaces of the heater cavity. Thus, the conductive heater is arranged spaced apart from at least one of the inner surface of the heater cavity. This allows thermal expansion of the conductive heater inside the heater cavity such that the thermal expansion of the conductive heater is not transferred to the structure of the reaction chamber. Thus, thermal expansion of the structure of the reaction chamber due to thermal expansion of the conductive heater may be avoided or minimized.

In some embodiments, the conductive heater is arranged inside the heater cavity of the reaction chamber.

In some other embodiments, the heater cavity is arranged inside the structure of the reaction chamber, and the conductive heater is arranged inside the heater cavity of the reaction chamber.

In some further embodiments, the conductive heater comprises the thermal element, and the thermal element is arranged inside the heater cavity of the reaction chamber.

In some yet further embodiments, the heater cavity is arranged inside the structure of the reaction chamber, the conductive heater comprises the thermal element, and the thermal element is arranged inside the heater cavity of the reaction chamber.

In some embodiments, the support part is arranged to form the base of the reaction chamber on which the substrate rack is provided. The heater cavity is provided to the base part of the reaction chamber.

In some other embodiments, the support part is arranged to form the base of the reaction chamber on which the substrate rack is provided. The heater cavity is provided inside the base part of the reaction chamber.

In some embodiments, the cover part forming the housing comprises reactor side walls and a reactor roof. The heater cavity is provided to the reactor roof, or the heater cavity is provided inside the reactor roof.

In some other embodiments, the cover part forming the housing comprises reactor side walls and a reactor roof. The thermal element is provided to the reactor side walls, or the thermal element is provided inside the reactor side walls.

In some further embodiments, the cover part forming the housing comprises reactor side walls and a reactor roof. The thermal element is provided to the reactor side walls and the reactor roof. or the thermal element is provided inside the reactor side walls and the reactor roof.

In some embodiments, the inner surfaces of the heater cavity are at least partly covered with heat absorbing material or provided with a heat absorbing material layer to increase heat transfer to structure of the reaction chamber.

In some embodiments, the heat absorbing material may carbide-based material or a metal with high thermal conductivity, such as aluminium. According to the invention the support part and the cover part together form the reaction chamber such that the cover part and the support part are movably arranged relative to each other between an open position of the reaction chamber and a closed position of the reaction chamber. The reaction chamber is therefore openable such that either the cover part moves away from the support part, or the support part moves away from the cover part, or both the support part and the cover part move away from each other. The movement direction of the cover part or the support part or both is preferably vertical. The atomic layer deposition apparatus further comprises a lifter connected to the reaction chamber and arranged to move the cover part between the open position and the closed position of the reaction chamber. Alternatively, the atomic layer deposition apparatus further comprises a lifter connected to the reaction chamber and arranged to move the support part between the open position and the closed position of the reaction chamber. Alternatively, atomic layer deposition apparatus further comprises at least one lifter connected to the reaction chamber and arranged to move the cover part and/or the support part between the open position and the closed position of the reaction chamber. The lifter is connected to the cover part of the reaction chamber and arranged to move the cover part in vertical direction relative to the support part of the reaction chamber, which the support part is arranged as stationary inside the vacuum chamber. Alternatively, the lifter is connected to the support part of the reaction chamber and arranged to move the support part in vertical direction relative to the cover part of the reaction chamber which the cover part is arranged as stationary inside the vacuum chamber. The lifter extends from outside the vacuum chamber through the vacuum chamber to the reaction chamber.

According to the invention the cover part is movably arranged relative to the support part, and the thermal element is provided to the cover part. Alternatively, the cover part is movably arranged relative to the support part, and the thermal element is provided to the support part. Alternatively, the cover part is movably arranged relative to the support part, and the thermal element is provided to the cover part and to the support part. The thermal element is thereby embedded either to the movable part of the reaction chamber i.e., the cover part of the reaction chamber or to the stationary part of the reaction chamber, i.e., the support part of the reaction chamber, or both to the movable part and to the stationary part of the reaction chamber.

According to the invention the support part is movably arranged relative to the cover part, and the thermal element is provided to the support part. Alternatively, the support part is movably arranged relative to the cover part, and the thermal element is provided to the cover part. Alternatively, the support part is movably arranged relative to the cover part, and the thermal element is provided to the cover part and to the support part. The thermal element is thereby embedded either to the movable part of the reaction chamber i.e., the support part of the reaction chamber, or to the stationary part of the reaction chamber, i.e., the cover part of the reaction chamber, or both to the movable part and to the stationary part of the reaction chamber.

According to the invention the reaction chamber comprises a thermally conductive material so that the thermal energy from the conductive heater arranged in connection with the reaction chamber is transferred to the reaction space of the reaction chamber. The thermal element of the conductive heater is embedded in the structures of the reaction chamber so that the conductive material surrounding the thermal element efficiently transfers thermal energy to the reaction space where the substrate rack is provided.

An arrangement for processing multiple substrates concurrently in a batch process according to the invention, the atomic layer deposition apparatus having a vacuum chamber, and a reaction chamber arranged inside the vacuum chamber, and a substrate rack arranged inside the reaction chamber for supporting substrates during an atomic layer deposition process, the reaction chamber comprises a conductive heater arranged to provide thermal energy to substrates provided at the substrate rack inside the reaction chamber. In other words, the arrangement comprises a vacuum chamber, a reaction chamber arranged inside the vacuum chamber and a substrate rack arranged inside the reaction chamber. The reaction chamber comprises a conductive heater having a thermal element embedded to the structure of the reaction chamber.

According to the invention the reaction chamber comprises a support part for supporting the substrate rack, and a cover part for forming a housing surrounding the substrate rack provided at the support part. The support part and the cover part are movably arranged relative to each other, and the conductive heater is arranged to the part movably arranged, or the conductive heater is arranged to the part stationary arranged, or the conductive heater is arranged both to the part movably arranged and to the part stationary arranged. In other words, the reaction chamber is openable such that either the cover part moves away from the support part, or the support part moves away from the cover part, or both the support part and the cover part move away from each other. The movement direction of the cover part or the support part or both is preferably vertical. The atomic layer deposition apparatus further comprises a lifter connected to the movable part or parts.

The thermal element may be provided to the support part forming a base of the reaction chamber on which the substrate rack is placed, or alternatively the thermal element may be provided to the cover part surrounding the substrate rack provided inside the reaction chamber.

The arrangement comprises the atomic layer deposition apparatus as described above.

An advantage of the invention is that the power rating and the number of heaters is minimized by using conductive heater in connection with the reaction chamber. Also, radiation heat waste to the vacuum chamber, which surrounds the reaction chamber, is minimized, because conductive heaters are heated to much lower temperature which is near the reaction chamber target temperature.

### BRIEF DESCRIPTION OF THE DRAWINGS

The invention is described in detail by means of specific embodiments with reference to the enclosed drawings, in which

FIG. 1 shows an atomic layer deposition apparatus and an arrangement according to the invention;

FIG. 2 an atomic layer deposition apparatus and an arrangement according to the invention;

FIG. 3 an atomic layer deposition apparatus and an arrangement according to the invention;

FIG. 4 an atomic layer deposition apparatus and an arrangement according to the invention;

FIG. 5 an atomic layer deposition apparatus and an arrangement according to the invention;

FIGS. 6 and 7 show atomic layer deposition apparatus and an arrangement according to the invention.

### DETAILED DESCRIPTION OF THE INVENTION

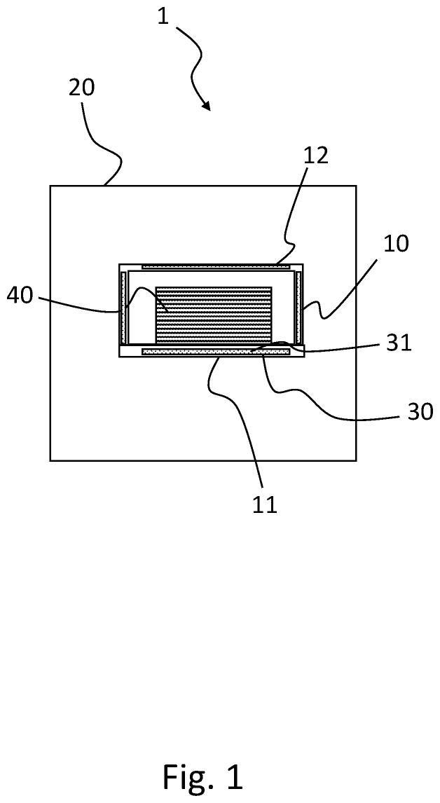

FIG. 1 shows an atomic layer deposition apparatus 1 which comprises a vacuum chamber 20 having a reaction chamber 10 inside the vacuum chamber 20. The reaction chamber 10 comprises a support part 11 and a cover part 12 which form together the reaction chamber 10 having a reaction space inside the reaction chamber 10. The arrangement of the invention also comprises a substrate rack 40 provided inside the reaction chamber 10. The conductive heater 30 is arranged to the reaction chamber 10 to provide thermal energy to substrates provided in the substrate rack 40 inside the reaction chamber 10. The conductive heater 30 may be provided anywhere to the structure of the reaction chamber 10. FIG. 1 shows the conductive heater 30 arranged to the support part 11 and to the cover part 12 but following figures show that the conductive heater 30 may be provided only to the cover part 12 or only to the support part 11.

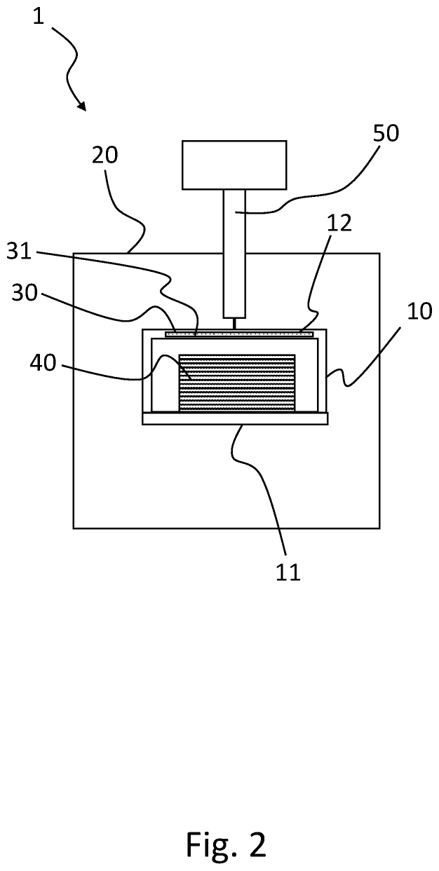

FIG. 2 shows the atomic layer deposition apparatus 1 having the vacuum chamber 20 and the reaction chamber 10 as described in connection with FIG. 1. In this embodiment, the conductive heater 30 is arranged in connection with the cover part 12 such that the thermal element 31 of the conductive heater 30 is arranged inside the roof of the cover part 12, i.e., inside the reactor roof. The cover part 12 is arranged movable relative to the support part 11 such that the support part 11 is stationary and the cover part 12 is arranged to move vertically away from the support part 11 to provide an open reaction chamber 10 and to move vertically toward the support part 11 to provide a closed reaction chamber 10. The substrate rack 40 is provided on the support part 11 which stays stationary. The lifter 50 is arranged to extend from outside the vacuum chamber 20 through the vacuum chamber 20 to the reaction chamber 10 and is connected to the cover part 12 of the reaction chamber 10 to provide vertical movement of the cover part 12 relative to the support part 11.

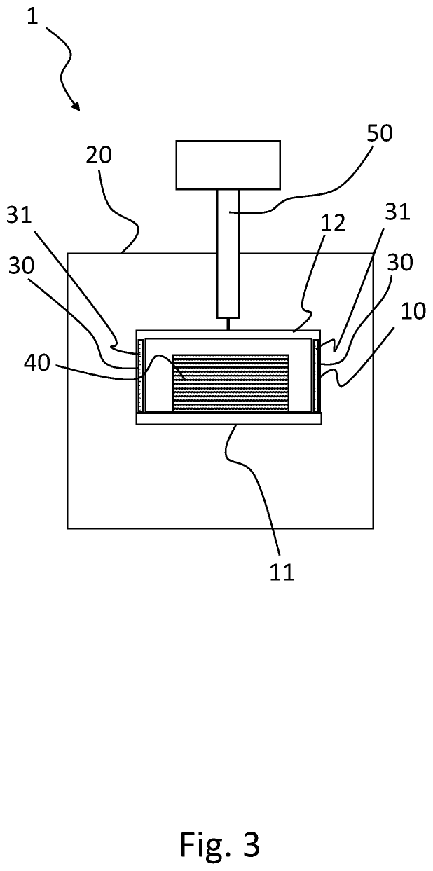

FIG. 3 shows the atomic layer deposition apparatus 1 having the vacuum chamber 20 and the reaction chamber 10 as described in connection with FIG. 1. In this embodiment, the conductive heater 30 is arranged in connection with the cover part 12 such that the thermal element 31 of the conductive heater 30 is arranged inside the side walls of the cover part 12. The atomic layer deposition apparatus 1 may comprise multiple conductive heaters which are provided inside one side wall or inside multiple side walls of the cover par 12. The cover part 12 is arranged movable relative to the support part 11 such that the support part 11 is stationary and the cover part 12 is arranged to move vertically away from the support part 11 to provide an open reaction chamber 10 and to move vertically toward the support part 11 to provide a closed reaction chamber 10. The substrate rack 40 is provided on the support part 11 which stays stationary. The lifter 50 is arranged to extend from outside the vacuum chamber 20 through the vacuum chamber 20 to the reaction chamber 10 and is connected to the cover part 12 of the reaction chamber 10 to provide vertical movement of the cover part 12 relative to the support part 11.

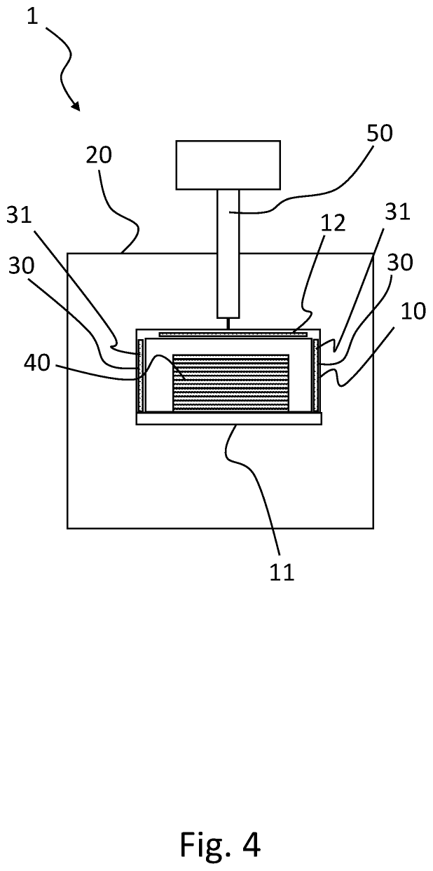

FIG. 4 shows a further embodiment of the atomic layer deposition apparatus 1 having the vacuum chamber 20 and the reaction chamber 10 as described in connection with FIG. 1. In this embodiment the conductive heaters 30 are arranged to the cover part 12 such that the thermal element extends throughout the covert part providing heat distribution evenly to the reaction space surrounded by the cover part 12. The thermal elements 31 may be provided separately in the reactor roof and the reactor side walls, or the thermal element 31 may extend embedded in the cover part 12 both in the roof and in the side walls. The conductive heater 30 is provided to the movable cover part 12 which is moved by the lifter 50 connected to the cover part 12.

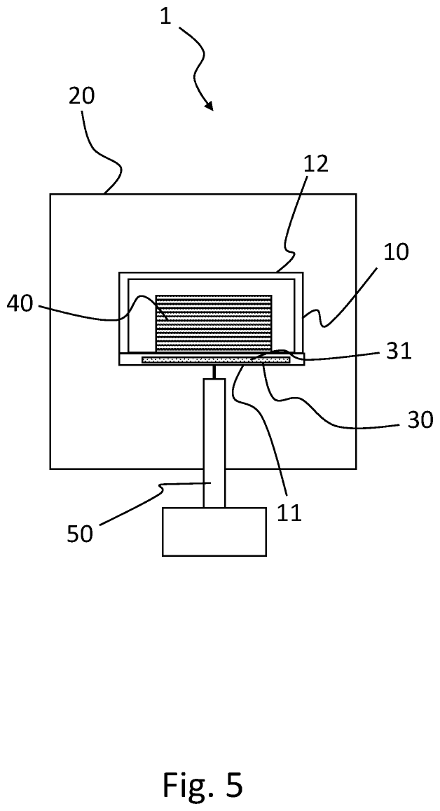

FIG. 5 shows a still further embodiment of the atomic layer deposition apparatus 1 having the vacuum chamber 20 and the reaction chamber 10 as described in connection with FIG. 1. In this embodiment the movable part is the support part 11 having the lifter 50 connected to it. The conductive heater 30 is provided to the support part such that the thermal element 31 is embedded to the support part 11.

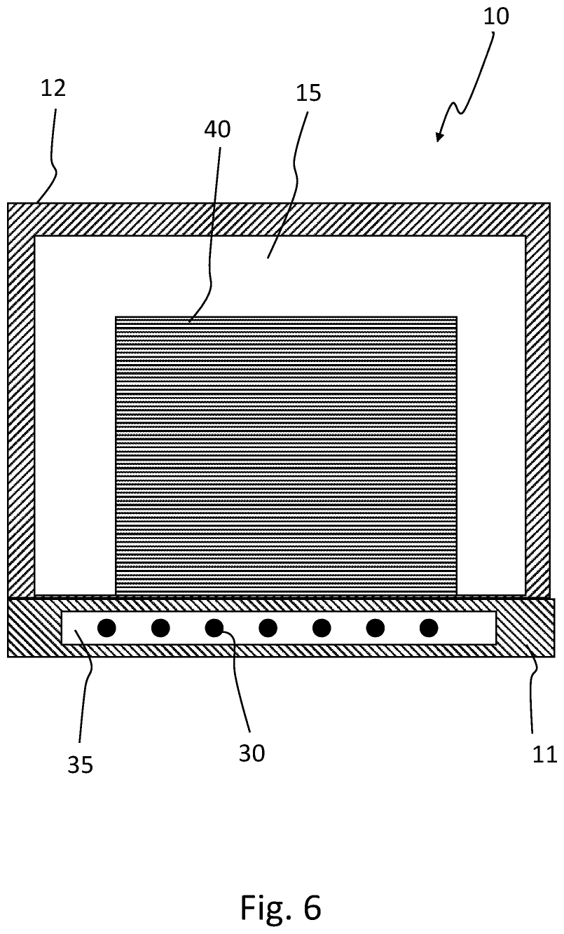

FIG. 6 shows an embodiment in which the reaction chamber 10 comprises a support part 11 and a cover part 12 which form together the reaction chamber 10 having a reaction space 15 inside the reaction chamber 10. The cover part comprises side walls 14 and the roof 13. The arrangement of the invention also comprises a substrate rack 40 provided inside the reaction chamber 10.

The structure of the reaction chamber 10 is provided with a heater cavity 35 having as heater cavity space. The heater cavity 35 is provided to the support part 11 of the reaction chamber 10. The conductive heater 30 is arranged inside the heater cavity 35.

As shown in FIG. 6, the conductive heater 30 is arranged inside heater cavity space of the heater cavity 35 in a loose fit.

In the embodiment of FIG. 6, the conductive heater 30 comprises an electric resistance heater arranged inside the heater cavity 35.

In an alternative embodiment, the conductive heater 30 comprises a thermal element 31 arranged inside the heater cavity 35.

The conductive heater 30 is arranged to the reaction chamber 10 to provide thermal energy to substrates provided in the substrate rack 40 inside the reaction chamber 10.

The heater cavity 35 and the conductive heater 30 may be provided anywhere to the structure of the reaction chamber 20.

FIG. 6 shows the heater cavity 35 arranged to the support part 11, and inside the support part 11. The conductive heater 11 is further arranged inside the heater cavity 35.

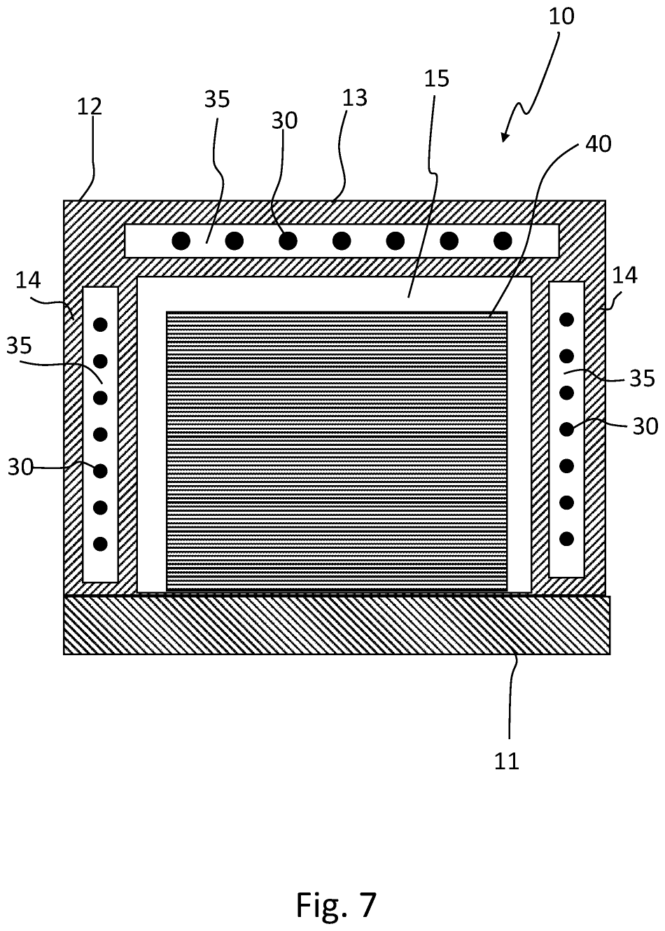

FIG. 7 shows the heater cavities 35 arranged to the cover part 12 of the reaction chamber 10. The side walls 14 of the reaction chamber 10 are provided with the heater cavity 35 and the conductive heater is arranged inside the heater cavity 35 of the side walls 14. The conductive heater 31 is arranged inside the heater cavity 35 of the side walls 14. The roof 13 of the reaction chamber 10 is also provided with the heater cavity 35 and the conductive heater is arranged inside the heater cavity 35 of the roof 13. The conductive heater 31 is arranged inside the heater cavity 35 of the roof 13.

As shown in FIG. 7, the heater cavity 35 of the side walls 14 and the heater cavity 35 of the roof 13 are provided as separate heater cavities and provided with separate or common conductive heater(s) 30.

In an alternative embodiment, the heater cavity 35 of the side walls 14 and the heater cavity 35 of the roof 13 one common heater cavity and provided with the conductive heater 30. The common heater cavity 35 may extend in the side walls 14 and in the roof 13. The invention has been described above with reference to the examples shown in the figures. However, the invention is in no way restricted to the above examples but may vary within the scope of the claims.

1.-16. (canceled)

17. An atomic layer deposition apparatus arranged to process multiple substrates concurrently in a batch process, the atomic layer deposition apparatus having a vacuum chamber, and a reaction chamber arranged inside the vacuum chamber, wherein the reaction chamber comprises:
a support part for supporting a substrate rack provided inside the reaction chamber, and
a cover part for forming a housing surrounding the substrate rack provided at the support part,
the atomic layer deposition apparatus further comprises:
a conductive heater arranged to the reaction chamber; the conductive heater is arranged to provide thermal energy to substrates provided in the substrate rack inside the reaction chamber.

18. The atomic layer deposition apparatus according to claim 17, wherein the conductive heater is arranged to the support part.

19. The atomic layer deposition apparatus according to claim 17, wherein the conductive heater is arranged to the cover part.

20. The atomic layer deposition apparatus according to claim 17, wherein:
the conductive heater is arranged inside a structure of the reaction chamber, or
the conductive heater is embedded inside material of the reaction chamber, or
the conductive heater comprises a thermal element arranged inside a structure of the reaction chamber, or
the conductive heater comprises a thermal element embedded inside material of the reaction chamber.

21. The atomic layer deposition apparatus according to claim 20, wherein the support part is arranged to form a base of the reaction chamber on which the substrate rack is provided, and
the thermal element is arranged inside the base of the reaction chamber.

22. The atomic layer deposition apparatus according to claim 20, wherein the cover part forming the housing comprises reactor side walls and a reactor roof, and
the thermal element is provided inside the reactor roof, or
the thermal element is provided inside the reactor side walls, or
the thermal element is provided inside the reactor side walls and the reactor roof.

23. The atomic layer deposition apparatus according to claim 17 claim, wherein:
the reaction chamber comprises a heater cavity, and the conductive heater is arranged inside the heater cavity of the reaction chamber, or
the reaction chamber comprises a heater cavity arranged inside a structure of the reaction chamber, and the conductive heater is arranged inside the heater cavity of the reaction chamber, or
the reaction chamber comprises a heater cavity, the conductive heater comprises a thermal element, and the thermal element is arranged inside the heater cavity of the reaction chamber,
the reaction chamber comprises a heater cavity arranged inside a structure of the reaction chamber, the conductive heater comprises a thermal element, and the thermal element is arranged inside the heater cavity of the reaction chamber.

24. The atomic layer deposition apparatus according to claim 23, wherein the support part is arranged to form a base of the reaction chamber on which the substrate rack is provided, and that:
the heater cavity is provided to the base part of the reaction chamber, or
the heater cavity is provided inside the base part of the reaction chamber.

25. The atomic layer deposition apparatus according to claim 23, wherein the cover part forming the housing comprises reactor side walls and a reactor roof, and that
the heater cavity is provided to the reactor roof, or
the heater cavity is provided inside the reactor roof, or
the thermal element is provided to the reactor side walls, or
the thermal element is provided inside the reactor side walls, or
the thermal element is provided to the reactor side walls and the reactor roof,
the thermal element is provided inside the reactor side walls and the reactor roof.

26. The atomic layer deposition apparatus according to claim 17, wherein the support part and the cover part together form the reaction chamber such that the cover part and the support part are movably arranged relative to each other between an open position of the reaction chamber and a closed position of the reaction chamber.

27. The atomic layer deposition apparatus according to claim 26, wherein the cover part is movably arranged relative to the support part, and
the conductive heater or the thermal element is provided to the cover part, or
the conductive heater or the thermal element is provided to the support part, or
the conductive heater or the thermal element is provided both to the support part and the cover part.

28. The atomic layer deposition apparatus according to claim 26, wherein the support part is movably arranged relative to the cover part, and
the conductive heater or the thermal element is provided to the support part, or
the conductive heater or the thermal element is provided to the cover part, or
the conductive heater or the thermal element is provided both to the support part and the cover part.

29. The atomic layer deposition apparatus according to claim 17, wherein the reaction chamber comprises a thermally conductive material so that the thermal energy from the conductive heater arranged in connection with the reaction chamber is transferred to the reaction space of the reaction chamber.

30. An arrangement for processing multiple substrates concurrently in a batch process, the arrangement comprises an atomic layer deposition apparatus having a vacuum chamber, and a reaction chamber arranged inside the vacuum chamber, and a substrate rack arranged inside the reaction chamber for supporting substrates during an atomic layer deposition process, wherein the reaction chamber comprises a conductive heater arranged to provide thermal energy to substrates provided at the substrate rack inside the reaction chamber.

31. The arrangement according to claim 30, wherein the reaction chamber comprises a support part for supporting the substrate rack, and a cover part for forming a housing surrounding the substrate rack provided at the support part,
the support part and the cover part are movably arranged relative to each other, and
the conductive heater is arranged to the part movably arranged, or
the conductive heater is arranged to the part stationary arranged, or the conductive heater is arranged both to the part movably arranged and to the part stationary arranged.

32. The arrangement for processing multiple substrates concurrently in a batch process, the arrangement comprises an atomic layer deposition apparatus having a vacuum chamber, and a reaction chamber arranged inside the vacuum chamber, and a substrate rack arranged inside the reaction chamber for supporting substrates during an atomic layer deposition process, wherein the reaction chamber comprises a conductive heater arranged to provide thermal energy to substrates provided at the substrate rack inside the reaction chamber, wherein the arrangement comprises an atomic layer deposition apparatus according to claim 17.
